(19) United States
(12) Patent Application Publication
(10) Pub. No.: US 2010/0212742 A1
(43) Pub. Date: Aug. 26, 2010

(54) PHOTOVOLTAIC DEVICE WITH CONCENTRATOR OPTICS

(75) Inventors: Axel Engel, Ingelheim (DE); Peter Nass, Mainz (DE); Ralf Jedamzik, Griesheim (DE); Simone Monika Ritter, Mainz (DE); Steffen Reichel, Mehlingen (DE); Ulrich Fotheringham, Wiesbaden (DE)

Correspondence Address: OHLANDT, GREELEY, RUGGIERO & PERLE, LLP, ONE LANDMARK SQUARE, 10TH FLOOR, STAMFORD, CT, 06901, US

(73) Assignee: SCHOTT AG

(21) Appl. No.: 12/711,568

(22) Filed: Feb. 24, 2010

(30) Foreign Application Priority Data
Feb. 24, 2009 (DE) 102009010116.0-33
Jun. 30, 2009 (DE) 10 2009 031 308.7

(51) Int. Cl. H01L 31/00

(52) U.S. Cl. 136/259

(57) ABSTRACT

The invention relates to a photovoltaic device having a concentrator optics. The photovoltaic device includes at least one solar cell and a concentrator optics, with the concentrator optics having at least one first, light-input-side, focusing optical element and at least one second optical element downstream of the first, light-input-side optical element and upstream of the solar cell, onto which, in operating position of the photovoltaic device, the bundled solar radiation falls by way of the first optical element, with the second optical element having a solarization-stabilized silicate glass.

### CROSS REFERENCE TO RELATED APPLICATIONS

This application claims benefit under 35 U.S.C. §119(a) of German Patent Application No. 10-2009-010-116.0-33, filed Feb. 24, 2009 and German Patent Application No. 10-2009-031-308.7, filed Jun. 30, 2009, the entire contents of both of which are incorporated herein by reference.

### BACKGROUND OF THE INVENTION

1. Field of the Invention

The invention relates, in general, to the field of photovoltaic power-generating devices. In particular, the invention relates to photovoltaic installations with concentrator optics.

2. Description of Related Art

Various approaches have been taken to lower the still high investment costs for photovoltaic installations. One approach lies in the development of low-cost solar cells. For example, materials that allow high-efficiency thin-layer solar cells to be produced at lower cost are being sought. In general, however, it may be said that the thin-layer cells that can be produced at lower cost do not approach more costly, particularly monocrystalline cells in terms of their efficiency.

Another approach lies in the use of high-efficiency solar cells, but then to lower the manufacturing costs through concentrator optics, because, by means of a concentrator optics, only a small fraction of the illuminated area needs to be occupied with solar cells.

Concentrator photovoltaics pursues the following approaches: Saving of semiconductor material through the use of an optical concentrator and increase in efficiency through the use of high-efficiency solar cells, such as, for instance, ultra-efficient triple solar cells. Accordingly, the use of optical concentrators makes it necessary to supply special optical components.

A drawback of concentrator optics is that, in this case, additional optical elements are employed, which should have long-term stability in order to prevent an unnecessary drop in efficiency. The optical properties of the elements are changed by solar radiation itself among other things. This problem arises particularly in the case when an optics with a number of elements connected in series is used, with the element or the elements that are downstream in the beam path or are arranged closest to the solar cell are insolated with concentrated sunlight.

### BRIEF SUMMARY OF THE INVENTION

The invention is therefore based on the problem of improving photovoltaic devices in terms of their long-term stability.

The invention may be employed for all light-transmitting elements of a photovoltaic device. The invention is especially suitable in places where, on account of high UV intensities, high transmission losses in glasses due to UV irradiation are to be expected with conventional glasses.

In particular, according to another aspect of the invention, a secondary optics is supplied, which has only a low and stationary solarization tendency and is therefore optimally suited for use as a secondary optics in concentrator photovoltaic installations.

The following general design principle is preferred for the device according to the invention: a primary optics focuses the sunlight onto the cell. In order to remedy optical flaws of this primary optics and to provide the greatest possible tolerances for the fabrication and mechanical alignment of the system depending on the current position of the sun, a secondary optics is additionally provided directly before the cell.

The primary optics is preferably refractive (Fresnel lens) or reflective (parabolic mirror). Particularly preferred as the secondary optics is a non-imaging lightpipe. The latter element should be of high transparency in the overlap region of the terrestrial solar spectrum and the sensitivity curves of conventional III-V semiconductors, such as, for instance, a triple cell. The overlap region in question extends from 300 nanometers (nm) to 1900 nm and thus includes, besides the visual region, also the infrared and the near-ultraviolet.

The components to be produced, as well as the materials used for coupling, should be capable of withstanding exposure to a high concentration of solar light—for instance, up to a 2,500-fold concentration—including the portion in the near UV.

However, intensive UV radiation can lead to the formation of defect centers in optical glasses, which, among other things, reduces the transmission at the UV edge. This effect is referred to as solarization. The greater this transmission loss is, the greater accordingly is also the power loss at the solar cell.

Solarization of glasses due to UV radiation was hitherto relevant in microlithography in particular.

Used in i-line lithography, for irradiation with light having a wavelength of 365 nm, are multicomponent glasses, which have been specially solarization-stabilized for the i-line.

Compared to the exposure occurring there, however, the use in a concentrator photovoltaic device is even more appreciably demanding. The usual solarization test for the i-line for materials consists typically in a exposure lasting 15 h to a UV lamp, which emits a radiated power of approximately 2000 W/m² onto the sample.

Without concentration, the power per unit area of sunlight falling on earth in Germany is up to 1000 Watts per square meter (W/m²) and, for concentration by a factor of 2500, a corresponding 2,500,000 W/m². Of this, approximately 50,000 W/m² is accounted for by the UV range of 300-400 nm. This estimate is based on the assumption of a black radiator with 5760 K color temperature for the sunlight. In more southern countries, even higher values are obtained. Thus, in North Africa, a power per unit area of about 2200 W/m² is attained even without concentration.

The value resulting for the range of 300-400 nm was further divided by five in order to take into account atmospheric absorption, which is particularly high in the UV. This corresponds roughly to the standard spectrum “AM1.5d low aod,” which contains approximately 2.2% UV-A. In the above estimate, only the UV portion above 300 nm was taken into consideration, because an encapsulation of the primary optics by the glass pane absorbing below 300 nm was assumed. However, the exposure does not last 15 hours here, as it does in the test for lithography optics, but rather service times of typically at least 20 years are required.

To solve this problem, the invention provides for a photovoltaic device having at least one solar cell and a concentrator optics, with the concentrator optics comprising at least one first, light-input-side, focusing optical element and at least one second optical element downstream of the first, light-input-side optical element and upstream of the solar cell, onto which, in operating position of the photovoltaic device, the bundled solar radiation falls by way of the first optical element, with the second optical element comprising at least one solarization-stabilized or low-solarization glass, preferably a solarization-stabilized or low-solarization silicate glass. Here, in terms of the invention, a solarization-stabilized glass refers, in particular, to a glass that, regardless of the insolated UV power, shows a saturation of the solarization effect, with the transmission at saturated solarization decreasing, in comparison to an unirradiated glass, by at most 0.03 on average over the wavelength range between 300 and 400 nm.

Alternatively or additionally, the glass can also be employed for the first, light-input-side, focusing optical element.

It has been found that certain silicate glasses fulfill the requirements of a low solarization tendency, with, in particular, it also being established that the solarization effect quickly reaches a level at which only a very low increase in absorption in comparison to an unirradiated glass takes place.

It has been found that admixture of titanium oxide to the silicate glass in an amount of at least 0.005 weight percent on oxide basis leads to especially low-solarization glasses.

Provided according to another aspect of the invention, therefore, is a photovoltaic device having at least one solar cell and a concentrator optics, with the concentrator optics comprising at least one optical element made of silicate glass, with the silicate glass containing titanium oxide in an amount of at least 0.005 weight percent on oxide basis. Although the use for a second element of the optics, which is downstream of the first, focusing element, is preferred, the glass may quite generally be used for any concentrator element of a photovoltaic device.

One class of glasses that is characterized by a low solarization that quickly reaches saturation consists of borosilicate glasses having the following constituents in weight percent on oxide basis:
SiO₂ 65-85, preferably 66-84, particularly preferably 67 to 83, more preferably 67-82 weight percent;
B₂O₃ 7-15, preferably 8-14 weight percent, particularly preferably 9-14 weight percent;
Al₂O₃ 0-10, preferably 0-9, particularly preferably 0 to 8 weight percent;
Na₂O 2-13 weight percent, preferably 2 to 12 weight percent, particularly preferably 2 to 11 weight percent;
K₂O 0-11 weight percent, preferably 0 to 10 weight percent, particularly preferably 0 to 9 weight percent;
Cs₂O 0-11 weight percent, preferably to 10 weight percent, particularly preferably to 9 weight percent;
MgO 0-0.5, preferably 0-0.3 weight percent;
CaO 0-3, preferably 0-2 weight percent;
SrO 0-0.5, preferably 0-0.3 weight percent;
BaO 0-6, preferably 0-5, particularly preferably 0-4 weight percent;
TiO₂ 0.005-1.5, preferably 0.005-1, particularly preferably 0.005 to 0.5, more preferably 0.005-0.03 weight percent;
Zr₂ 0-0.5, preferably 0-0.3 weight percent;
CeO₂ 0-3, preferably 0-2 weight percent; and
F 0-0.6, preferably 0-0.5, particularly preferably 0-0.4 weight percent.

Compared to the glasses described in DE 100 05 088 C1, the borosilicate-glasses according to the above composition differ in their lower contents of Al₂O₃ and CaO.

This glass can contain one or more of the following fining agents in weight percent on oxide basis, without markedly worsening the solarization tendency:
NaCl 0-2, preferably 0-1, particularly preferably 0-0.5 weight percent;
As₂O₃ 0-0.03, preferably 0-0.02 weight percent; and
Sb₂O₃ 0-1, preferably 0-0.5 weight percent.

Although arsenic oxide leads, in general, to a greater solarization, an admixture up to the above-given limit of 0.02 weight percent has not proven to be detrimental.

A solarization may be caused by, among other things, a photoinduced oxidation or reduction of polyvalent components. According to a preferred further development of the invention, therefore, the glass of the second optical component is free or at least largely free of polyvalent components. To be mentioned as detrimental polyvalent components are, for example, iron oxide, cobalt oxide, chromium oxide, copper oxide, and manganese oxide. Therefore, in further development of the invention, iron oxide, cobalt oxide, chromium oxide, copper oxide, and manganese oxide are each contained in the glass at less than 4 parts-per-million (ppm), preferably less than 3 ppm, particularly preferably less than 2 ppm.

According to a further development of the invention, the solarization-stabilized silicate glass contains, in addition, the following constituents in weight percent on oxide basis:
Li₂O 0-2 weight percent;
PbO 0-2 weight percent;
SnO₂ 0-1 weight percent;
WO₃ 0-0.5 weight percent; and
Bi₂O₃ 0-0.5 weight percent.

Another glass composition that fulfills the requirements placed on a concentrator optics in terms of a high solarization stability, even under extremely high radiation intensity, contains the following constituents in weight percent on oxide basis:
SiO₂ 31-55, preferably 32-54, particularly preferably 33-53 weight percent,
PbO 15-65, preferably 16-64, particularly preferably 17-63, more preferably 18-62 weight percent,
Al₂O₃ 0-8, preferably 0-7, particularly preferably 0-6 weight percent,
Na₂O 0.1-9 weight percent, preferably 0.1-8, particularly preferably 0.1-7.5 weight percent,
K₂O 1-13 weight percent, preferably 1-12, particularly preferably 1.5-11 weight percent,
BaO 0-17 weight percent, preferably 0-16, particularly preferably 0-15 weight percent,
ZnO 0-11, preferably 0-10, particularly preferably 0-9 weight percent, as well as, if need be, fining agents, such as, for example,
As₂O₃ 0-0.02 weight percent, and/or
Sb₂O₃ 0-1 weight percent.

This lead silicate glass allows high refractive indices to be attained, which, depending on the design of the respective optical element, can be of great advantage. Even though lead oxide can occur in several oxidation states, a glass having the preceding composition shows, even under the high radiated power occurring in a concentrator optics, an only very low solarization, which quickly reaches saturation.

Yet another type of glass, which has a very low tendency toward solarization, contains the following constituents in weight percent on oxide basis:
SiO₂ 65-75, preferably 66-74, particularly preferably 67-72 weight percent,
B₂O₃ 0-3, preferably 0-2 weight percent,
Al₂O₃ 0-7, preferably 0-6, particularly preferably 0-5 weight percent,
Na₂O 5-16, preferably 6-15, particularly preferably 7-14 weight percent,
K₂O 0.5-12 weight percent, preferably 0.5-11, particularly preferably 0.5-10 weight percent,
MgO 0-7, preferably 0-6, particularly preferably 0-5 weight percent,
CaO 2-10, preferably 2-9, particularly preferably 3-8 weight percent,
BaO 0.5-7 weight percent, preferably 0.5-6, particularly preferably 0.5-5 weight percent,
ZnO 0.5-7, preferably 0.5-6, particularly preferably 0.5-5 weight percent,
TiO₂ 0-1, preferably 0-0.5 weight percent
NaCl 0-2 weight percent,
As₂O₃ 0-0.02 weight percent, and
Sb₂O₃ 0-1 weight percent.

According to a preferred embodiment of the invention, the second optical element is a lightpipe, which guides the light that is bundled by the first optical element on a light input side of the lightpipe to the light output side. In this case, the solar cell is arranged along the optical path preferably directly on the light output side. If need be, however, there can be a spacing between the solar cell and the light output side, with the interposition of one or more further optical elements also being conceivable. It is advantageous, however, to provide for a direct coupling of the solar cell to the light output face of the lightpipe so as to reduce reflection losses at the light output face.

The lightpipe serves to make more uniform the lateral intensity distribution of the light that is bundled by the focusing first element, so that the solar cell is illuminated as uniformly as possible across its area. Mentioned as example is a caustic formed for a device that is not aligned exactly to the sun or a focus that is smaller than the area of the solar cell. In both cases, the light intensity across the solar cell can then vary quickly by one or more orders of magnitude. The locally increased light intensity shortens the lifetime of the solar cell. Moreover, the efficiency drops for non-uniform illumination when some regions of the solar cell work at saturation and other regions are not illuminated or hardly illuminated.

Accordingly preferred as a lightpipe, as stated already above, is a non-imaging lightpipe.

Suitable to achieve a homogenization of the light distribution is particularly a lightpipe in the form of a rod with square cross section, preferably one having linear side faces in the direction transverse to the longitudinal direction. The rod can, if need be, also have a conical shape for further concentration of the light and for mitigating the requirements placed on alignment to the sun, with the front face of smaller cross-sectional area forming the light output face. According to another further development of the invention, the lightpipe is designed as a plate, with two opposite-lying edge faces forming the light input and light output faces. This is appropriate when longitudinally focusing first optical elements, such as, for instance, cylindrical lenses or Fresnel lens acting as cylindrical lenses or cylindrically focusing reflectors, are employed. The plate, too, can have a varying thickness, so that it is tapered from the light input face to the light output face. Also possible are other elements and concentrator geometries, such as, for instance, a compound parabolic reflector as concentrator or second optical element.

The corners, in conjunction with linear side faces, result in the light beams being reflected at the side walls in a non-focusing manner. As a result, direct or distorted images of the input-side spatial beam distribution are prevented on the light output side even for short lengths of the lightpipe. The mean number of reflections and thus also the length of the lightpipe play a role in the homogenization of the light. In this case, it is preferred to make the lightpipe be at least 1.5 times, preferably at least 2.5 times, as long as the lateral dimension of the cross section of the light output face that is relevant for the number of reflections.

In order to keep the manufacturing costs for the concentrator optics as low as possible, it is further advantageous to form the glass element containing the solarization-stabilized glass by pressing. Accordingly, in this further development of the invention, the optical element containing the glass, in particular the second optical element downstream of the first, focusing element, is constructed as a pressed glass part.

An effect that has been observed to be particularly advantageous for the glasses of the invention is also the at least partial curing of the solarization, which, in any case, is only small, by tempering of the glass. In this process, temperatures of 200 degrees Celsius (° C.) were already adequate in order to reverse transmission degradation caused by solarization. It is assumed that even temperatures starting at 100° C. are adequate in order to bring about a relaxation of the solarization. According to yet another further development of the invention, therefore, a heating device to heat the glass to at least 100° C. can be provided. This heating can be achieved, in a particularly simple way, also by the impinging solar radiation, with it being possible in this case to set up the device in such a way that the heat supply at the glass element is also adequately large compared to the heat dissipation so as to attain a temperature of at least 100° C., preferably at least 150° C.

In general, the invention is suitable for particularly effective, high-value solar cells in order to be able to exhaust in full the advantages of the concentrator optics. Accordingly, triple solar cells or triple junction solar cells are particularly suitable. Other solar cells, such as, for instance, in general, monocrystalline elements can also be used, however.

Furthermore, the glass can also be coated in order to provide, for instance, an antireflection property and/or a scratch protection so as to increase the transmission over the long term.

Glasses according to the invention are characterized by a very low density of defect centers activated UV radiation. It was found that a strong solarization under conditions that are relevant for efficiency in solar cell application can be prevented when the density of UV-light-induced defects in the silicate glass is less than 3×10¹⁸ cm³.

The invention will now be explained in more detail below on the basis of exemplary embodiments and with reference to the attached figures, in which the same reference signs refer to the same or corresponding elements.

### BRIEF DESCRIPTION OF THE SEVERAL VIEWS OF THE DRAWINGS

FIG. 1 illustrates a photovoltaic device,

FIG. 2 a view of the lightpipe of the arrangement illustrated in FIG. 1,

FIG. 3 a variant of the device shown in FIG. 1 with a cylindrically focusing reflector,

FIG. 4 plots of the spectral transmission of two glasses before and after UV irradiation, and

FIG. 5 determined relaxation times of the solarization of a glass that is suitable for the invention.

### DETAILED DESCRIPTION OF THE INVENTION

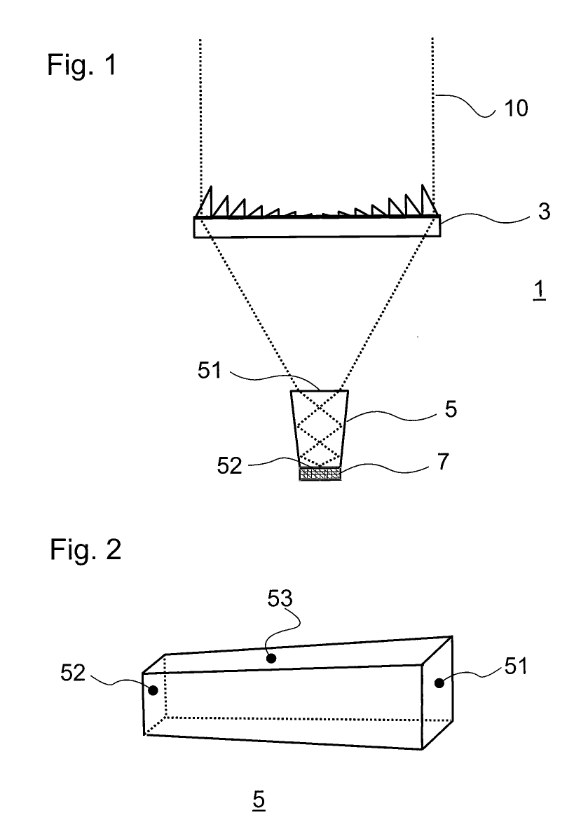

FIG. 1 shows a photovoltaic device, referred to in its entirety by the reference sign 1. The photovoltaic device 1 comprises at least one solar cell 7 in the form, for example, of a high-efficiency triple-junction solar cell and a concentrator optics. The concentrator optics, in turn, comprises two elements. In particular, at least one first, light-input-side, focusing optic element 3 and one second optical element 5 connected downstream of the first, light-input-side, focusing element 3 and upstream of the solar cell 7. In the operating position of the photovoltaic device, that is, when it is aligned in the direction of impingement of solar light, the bundled solar radiation falls by way of the first optical element 3 onto the second optical element. In order to highlight the beam path, two light beams 10 of the impinging sunlight are illustrated.

For the example shown in FIG. 1, the first optical element is a Fresnel lens. The second optical element is constructed as a short lightpipe having a light input face 51 and a light output face 52. In this case, the lightpipe is at least 1.5 times, preferably at least 2.5 times as long as the smallest lateral dimension of the cross section of the light output face 52.

The lightpipe is fabricated from silicate glass as a pressed part. The glass is solarization-stabilized, with the silicate glass showing a saturation of the solarization effect regardless of the insolated UV power. In this case, the transmission decreases for saturated solarization in comparison to an unirradiated glass by at most 0.03 on average over the wavelength range between 300 and 400 nanometers.

The lightpipe has a slightly conical construction and tappers from the light input face 51 to the light output face. A view of the lightpipe is illustrated in FIG. 2. As can be seen on the basis of FIG. 2, the lightpipe not only has a slightly conical shape, but also has a square cross section. By way of example, the light input face 51 and the light output face 52 can each have a square cross section.

Differently from what is illustrated in FIG. 2, the lightpipe can also taper in a shape other than conical to the light output face 52. In any case, the side faces in the direction perpendicular to the longitudinal direction are linear. As a result, focusing effects during reflection at the side walls, which can contribute to inhomogeneities in the lateral light distribution on the light output side, are prevented.

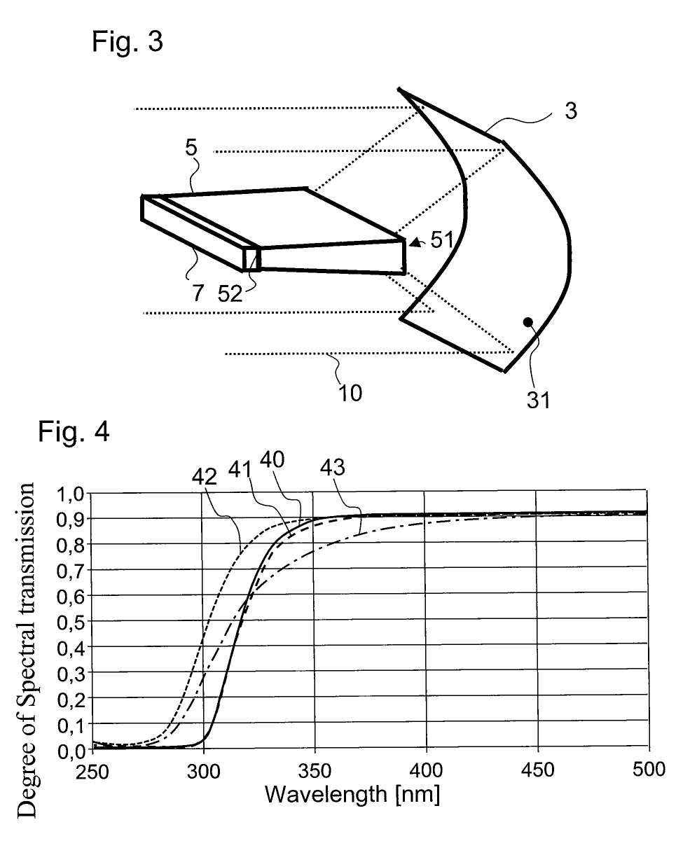

An example of a photovoltaic device having a cylindrically focusing first optical element 3 is illustrated in FIG. 3. In this arrangement, by way of example, the first optical element is constructed as a cylindrically focusing reflector. In general, without limitation to the exemplary embodiment of FIG. 3, cylindrically focusing does not mean that the reflector face is cylindrical, but rather that the focusing take place in only one direction in the manner of a cylindrical lens. Thus, also in the example shown in FIG. 3, the reflector face 31 is bent parabolically.

In this example, the second optical element 5 is also constructed as a lightpipe, which, in this case, is only plate-shaped, with the light input face and light output face forming opposite-lying edges of the plate and the plate being tapered toward the light output face 52, on which a striplike solar cell 7 is arranged, by decreasing the thickness of the plate.

FIG. 4 shows, for illustration, diagrams of the spectral transmission as a function of the wavelength for two glasses, each before intensive UV irradiation and, afterwards, also in the solarized state.

A preferred glass for the second optical element contains the following constituents in weight percent on oxide basis:
SiO₂ 65-85 weight percent,
B₂O₃ 7-15 weight percent,
Al₂O₃ 0-10 weight percent,
Na₂O 2-13 weight percent,
K₂O 0-11 weight percent,
Cs₂O 0-11 weight percent,
MgO 0-0.5 weight percent,
CaO 0-3 weight percent,
SrO 0-0.5 weight percent,
BaO 0-6 weight percent,
TiO₂ 0.005-1.5 weight percent,
ZrO₂ 0-0.5 weight percent,
CeO₂ 0-3 weight percent,
F 0-0.6 weight percent.

In this case, it was surprisingly found that, for this glass, which can be included among the borosilicate crown glasses, especially the titanium proportion of this borosilicate glass contributes to the fact that the solarization quickly reaches saturation, so that a very high transmission is also maintained at the UV edge of the material. It is possible to employ also somewhat lower titanium oxide contents. Preferably, however, the titanium oxide content contributes at least 0.005 weight percent on oxide basis. The curves 40 and 41 in FIG. 2 show the spectral transmission plots of such a glass. In this case, the curve 40 is the spectral transmission plot before the irradiation with a UV lamp and the curve 41 is the spectral transmission plot after the irradiation, that is, the plot of the solarized glass.

Shown for comparison are the spectral transmissions of a glass of comparable composition before the irradiation (curve 42) and afterwards (curve 43). The glass on which these curves were measured has no measurable proportions of titanium oxide. The comparison of the curves 40 and 42 shows that the titanium-free glass, in itself, even has a higher transmission in the UV region. However, it is found that the transmission in the UV region for the titanium glass appreciably declines after the irradiation (curve 43), with transmission losses extending far into the visible region.

By contrast, the transmission for the irradiated glass according to the invention is hardly influenced by the UV irradiation. In the wavelength range between 300 and 400 nanometers, the decline in the transmission consistently lies markedly less than 0.05. Measured, in particular, was a value of the transmission reduction of approximately 1.4% at the UV edge. Averaged over this wavelength range, the decline is markedly less than 0.03. By contrast, the transmission reduction of the comparison glass is up to about 0.2 (at 320 nanometers).

The transmission of the glass according to the invention also remains at the attained level, regardless of the power or duration of the insolated UV radiation. This stabilization of the solarization ensures a special suitability of the glass for use as secondary optics in a concentrator, because it is ensured that the solarization effect (the remaining solarization) is not scaled with the supplied light power, but rather the transmission remains in saturation at a high transmission level, regardless of the supplied UV power.

The observed rapid saturation of the solarization in the glasses according to the invention may be due, on the one hand, to the fact that only a small density of defect centers is at all possible and, on the other hand, to the fact that thermal relaxation of the defect centers is especially strongly pronounced. For the glasses according to the invention, it is assumed that only a low maximum possible concentration of defect centers is decisive.

This effect of rapid saturation of the solarization, as was observed for optical elements for the device according to the invention, will be explained in more detail below on the basis of a model.

The solarization achieved can generally be described by a rate equation of production and annihilation of UV-induced defects with time. In this case, the production rate E can be set proportional to the difference between the maximum possible density of UV-induced defects nₘₐₓ and the current density of these defects n:

E=γ_{production}+(nₘₐₓ−n)

Here, γ is a constant, which is inversely proportional to the time constant of the buildup of the solarization effect. It is dependent on the UV intensity.

The annihilation rate V is set proportional to the current density of UV-induced defects:

V=γₐₙₙᵢₕᵢₗₐₜᵢₒₙ×n

The constant γₐₙₙᵢₕᵢₗₐₜᵢₒₙ is inversely proportional to the time constant of the relief of the solarization effect. It has been found that this constant generally depends on the temperature.

Both rates are equal at equilibrium and the following holds:

n=nₘₐₓ×γ_{production}/(γ_{production}+γₐₙₙᵢₕᵢₗₐₜᵢₒₙ)

However, this means that, regardless of the UV intensity, n assumes the value nₘₐₓ when γ_{production}>>γₐₙₙᵢₕᵢₗₐₜᵢₒₙ.

The inverse of the rate is the characteristic time for the respective process. It was demonstrated that the characteristic time for the annihilation (curing) of defects caused by solarization lies at over 6 hours at room temperature.

Solarization measurements using the HOK-4 lamp have shown that, even after less than one hour and not only after 15 hours, a constant value is attained, which supports the fact that the time constant of the relief of the solarization effect already lies at less than one hour in the HOK-4 lamp test. This must apply all the more to the UV intensities that occur in a concentrator photovoltaic installation. Accordingly, the production rate is always appreciably higher than the annihilation rate and the saturation value of the defect center concentration corresponds essentially to the maximum possible value nₘₐₓ.

After irradiation using an HOK-4 lamp, the glass according to the invention shows a very slight decline in transmission. This no longer worsens, according to what has been stated, due to further or more intensive irradiation. A saturation of the solarization effect arises at low level.

It is therefore assumed that, for the glasses according to the invention, only a very low maximum density of defect centers nₘₐₓ can form and this concentration is reached relatively quickly. These are not obvious properties of glasses, because a solarization effect is typically built up slowly and saturation values are attained at markedly higher level.

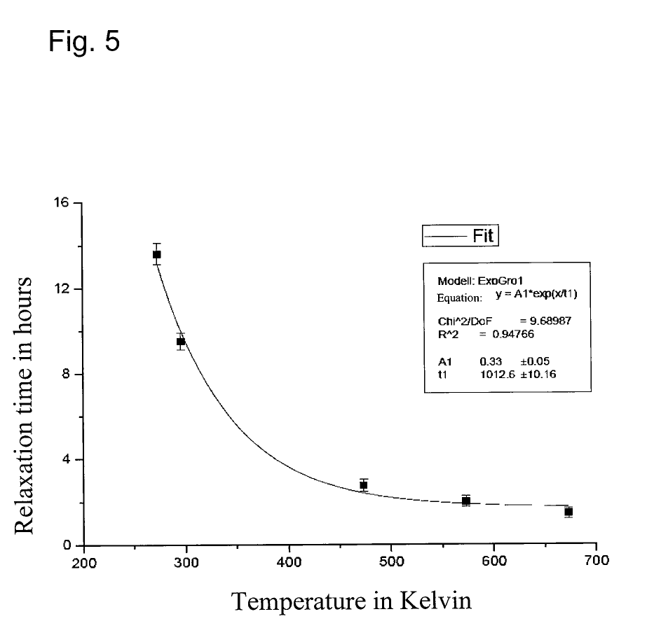

The relaxation times measured for the glasses according to the invention are more than 6 hours, extrapolated to room temperature. At 200° C., the relaxation times are less than three hours. In this regard, FIG. 5 shows the relaxation times of the above-mentioned glass as a function of temperature.

The determination of the relaxation times was carried out as follows. Round samples having a diameter of 18 millimetres (mm) and a thickness of approximately 1 mm were prepared from the glass according to the invention.

The investigations were carried out using transmission spectrometers of the type Lambda 900 and Lambda 950. In this case, a complete spectrum of 250-850 nm wavelength was recorded for determination of the solarization.

For the determination of the relaxation time, the irradiated samples were placed in a heating cuvette and the time course of the transmission was determined for a wavelength of 345 nm.

The curing was then investigated at a wavelength of 345 nm, because, here, too, in accordance with FIG. 4, the maximum change was observed. The time change of the induced solarization (=increase in the transmission) was recorded. An exponential function was chosen for fitting to the measured values.

A=A₀×exp [−t/τᵣₑₗₐₓ]

The curing of the UV-induced absorption is described by the exponential factor in Equation (1) with the relaxation time τᵣₑₗₐₓ typical for the material. This relaxation time, in turn, is, as stated, temperature-dependent and can be described by the relation

τᵣₑₗₐₓ=τ₀×exp [+H_{τ}/RT]

Here, τ₀ and H_{τ} are material-typical constants, R represents the gas constant, and T is the absolute temperature in K.

Presented in FIG. 5 are the determined relaxation times. The solid curve is the exponential function according to Equation (2) established by way of the three relaxation times.

The following parameter values of Equation (1) were determined by fitting:

| τ₀ | H_{τ}/R |
|---|---|
| [hours] | [Kelvin] |
| 0.33 ± 0.05 | 1012.6 ± 10.2 |

The relaxation times at the various temperatures, as shown in FIG. 5 and determined on the basis of Equation (2), can be regarded as characteristic for glasses that are suitable in accordance with the invention. At room temperature, the relaxation times are more than 6 hours and thus markedly longer than the times that are needed for generation of solarization up to the saturation limit. At temperatures between 200° C. and 400° C., the relaxation time in this case is less than 3 hours. Accordingly provided, according to an embodiment of the invention, without limitation to the exemplary embodiment, is a photovoltaic device having at least one solar cell and a concentrator optics, with the concentrator optics comprising a glass element, the glass of which has a relaxation time (τᵣₑₗₐₓ) of the solarization of less than 3 hours at a temperature in a range of 200° C. to 400° C. In this case, the relaxation time τᵣₑₗₐₓ can be determined through measurement of the time plot of the transmission at 345 nanometers under storage at a temperature in the cited range after UV exposure up to saturation of the solarization and fitting of a curve according to Equations (1) to (3). Preferably, such a glass is employed, in turn, in a two-part concentrator optics as a second optical element, on which the bundled solar radiation is directed by way of the first optical element.

It has been found that the glasses according to the invention generally have a low density of UV-induced defects. This defect density, even in the saturated state of the solarization, is generally less than 3×10¹⁸ cm⁻³.

On the basis of the glass with the transmission plots 40 and 41 in FIG. 2, the defect concentration can be estimated as follows:

The Ti⁴⁺ ions in the glass provide for an effective UV blocking. The cut-off of the transmission at which the transmission value at the UV edge drops to 50% lies between a wavelength of 315 and 320 nm. From the comparison of the curves 40 and 41 in FIG. 4, a reduction of the transmission at 345 nm by 1.4% results.

For the spectral absorption coefficients A, the following holds:

$$A = - \frac{1}{d} \cdot log ( \frac{T}{P} )$$

In this relation, d represents the density of the glass, T the measured transmission, and P the maximum possible transmission value. For the value of P, no absorption in the glass is assumed. Instead, transmission losses are created only by Fresnel losses, that is, reflections at the boundaries.

At a wavelength of 345 nm, the absorption coefficient is approximately 6.0×10⁻³ mm⁻¹.

After UV irradiation in the state of saturated solarization, this value increases to approximately 8.6×10⁻³ mm⁻¹. This increase in absorption by 2.6×10⁻³ mm⁻¹ is caused by the UV-light-induced defects. Accordingly, by means of the relation

$$n = \frac{A}{σ}$$

with a typical effective absorption cross section σ for the defect centers in the range of 10⁻¹⁸ mm², a UV-induced defect density of n≈3×10¹⁵ mm⁻³=3×10¹⁸ cm⁻³=30 ppm results.

It is obvious to the skilled practitioner that the invention is not limited to the exemplary embodiments described above, but rather can be varied in diverse manner in the framework of the claims below and combinations thereof. Thus, for example, if a lightpipe is employed, for instance, as a secondary optical element, as is illustrated, by way of example, in FIGS. 1 and 3, two different glasses, for example, may be combined so as to create the lightpipe as a core-jacket lightpipe.

What is claimed is:

1. A photovoltaic device comprising:
at least one solar cell; and
a concentrator optics, wherein the concentrator optics comprises at least one first, light-input-side, focusing optical element and at least one second optical element downstream of the first, light-input-side optical element and upstream of the solar cell, onto which, in operating position of the photovoltaic device, the bundled solar radiation falls by way of the first optical element, with the second optical element comprising a solarization-stabilized silicate glass.

2. The photovoltaic device according to claim 1, wherein the solarization-stabilized silicate glass shows, regardless of the insolated UV power, a saturation of the solarization effect, with the transmission for saturated solarization dropping, in comparison to an unirradiated glass, by at most 0.03 on average over the wavelength range between 300 and 400 nm.

3. The photovoltaic device according to claim 1, wherein the solarization-stabilized silicate glass contains titanium oxide in an amount of 0.005 weight percent on oxide basis.

4. The photovoltaic device according to claim 3, wherein the solarization-stabilized silicate glass is a borosilicate glasses comprising, in weight percent on oxide basis:
SiO₂ 65-85 weight percent,
B₂O₃ 7-15 weight percent,
Al₂O₃ 0-10 weight percent,
Na₂O 2-13 weight percent,
K₂O 0-11 weight percent,
Cs₂O 0-11 weight percent,
MgO 0-0.5 weight percent,
CaO 0-3 weight percent,
SrO 0-0.5 weight percent,
BaO 0-6 weight percent,
TiO₂ 0.005-1.5 weight percent,
Zr₂O 0-0.5 weight percent,
CeO₂ 0-3 weight percent, and
F 0-0.6 weight percent.

5. The photovoltaic device according to claim 4, wherein the solarization-stabilized silicate glass further comprises fining agents, in weight percent on oxide basis, of:
NaCl 0-2 weight percent,
As₂O₃ 0-0.02 weight percent, and
Sb₂O₃ 0-1 weight percent.

6. The photovoltaic device according to claim 1, wherein the solarization-stabilized silicate glass of the second optical component is at least substantially free of polyvalent components.

7. The photovoltaic device according to claim 6, wherein the solarization-stabilized silicate glass of the second optical component is free of polyvalent components.

8. The photovoltaic device according to claim 6, wherein the solarization-stabilized silicate glass comprises each of iron oxide, cobalt oxide, chromium oxide, copper oxide, and manganese oxide at less than 4 parts-per-million.

9. The photovoltaic device according to claim 6, wherein the solarization-stabilized silicate glass comprises each of iron oxide, cobalt oxide, chromium oxide, copper oxide, and manganese oxide at less than 3 parts-per-million.

10. The photovoltaic device according to claim 6, wherein the solarization-stabilized silicate glass comprises each of iron oxide, cobalt oxide, chromium oxide, copper oxide, and manganese oxide at less than 2 parts-per-million.

11. The photovoltaic device according to claim 4, wherein the solarization-stabilized silicate glass further comprises, in weight percent on oxide basis:
Li₂O 0-2 weight percent,
PbO 0-2 weight percent,
SnO₂ 0-1 weight percent,
WO₃ 0-0.5 weight percent, and
Bi₂O₃ 0-0.5 weight percent.

12. The photovoltaic device according to claim 1, wherein the second optical element is a lightpipe that guides light bundled by the first optical element on a light input side of the lightpipe to a light output side of the lightpipe.

13. The photovoltaic device according to claim 12, wherein the lightpipe is a rod having square cross section or a plate.

14. The photovoltaic device according to claim 12, wherein the light output side of the lightpipe has a cross section with a minimum lateral dimension and wherein the lightpipe is at least 1.5 times as long as the minimum lateral dimension.

15. The photovoltaic device according to claim 14, wherein the lightpipe is at least 2.5 times as long as the minimum lateral dimension.

16. The photovoltaic device according to claim 1, wherein the solarization-stabilized silicate glass comprises a lead silicate glass that comprises, in weight percent on oxide basis:
SiO₂ 31-55 weight percent,
PbO 15-65 weight percent,
Al₂O₃ 0-8 weight percent,
Na₂O 0.1-9 weight percent,
K₂O 1-13 weight percent,
BaO 0-17 weight percent
ZnO 0-11 weight percent,
As₂O₃ 0-0.2 weight percent, and
Sb₂O₃ 0-1 weight percent.

17. The photovoltaic device according to claim 1, wherein the solarization-stabilized silicate glass comprises, in weight percent on oxide basis:
SiO₂ 65-75 weight percent,
B₂O₃ 0-3 weight percent,
Al₂O₃ 0-7weight percent,
Na₂O 5-16 weight percent,
K₂O 0.5-12 weight percent,
MgO 0-7 weight percent,
CaO 2-10 weight percent,
BaO 0.5-7 weight percent,
ZnO 0.5-7 weight percent,
TiO₂ 0-1.5 weight percent
As₂O₃ 0-0.2 weight percent, and
Sb₂O₃ 0-1 weight percent.

18. The photovoltaic device according to claim 1, wherein the second optical element is a pressed glass part.

19. The photovoltaic device according to claim 1, further comprising a heating device to heat the silicate glass to a temperature of at least 100° C.

20. The photovoltaic device according to claim 1, wherein the at least one solar cell comprises a triple solar cell.

21. The photovoltaic device according to claim 1, wherein the solarization-stabilized silicate glass has a relaxation time of the solarization of less than 6 hours at a temperature in a range of 200° C. to 400° C.

22. The photovoltaic device according to claim 1, wherein the solarization-stabilized silicate glass is configured so that UV light induces a density of defects of less than 3×10¹⁸ cm⁻³.
